(19) United States
(12) Patent Application Publication
(10) Pub. No.: US 2010/0072587 A1
(43) Pub. Date: Mar. 25, 2010

(54) IC SOCKET HAVING HEAT DISSIPATION FUNCTION

(76) Inventor: Masahito Naito, Tokyo (JP)

Correspondence Address: 3M INNOVATIVE PROPERTIES COMPANY, PO BOX 33427, ST. PAUL, MN, 55133-3427, US

(21) Appl. No.: 12/444,440

(22) PCT Filed: Oct. 18, 2007
(86) PCT No.: PCT/US07/81719

§ 371 Date: Apr. 6, 2009

(30) Foreign Application Priority Data
Oct. 30, 2006 (JP) 2006-294629

(51) Int. Cl. H01L 23/495

(52) U.S. Cl. 257/675; 257/E23.031

(57) ABSTRACT

It is an object of the present invention to provide an IC socket that has a configuration to promote heat dissipation from an IC device in a simple configuration, and prevent overheating of the IC device under test. Contact pins 6c, similar to the contact pins 6a and 6b, are disposed in regions not corresponding to the signal balls 51 and the thermal balls 52 of the BGA device 5. Further, the contact pins 6c and the second contact pins 6b that are contacted to the thermal balls 52 are thermally connected to each other via a heat spreader.

### TECHNICAL FIELD

The present invention relates to an electric-connection integrated circuit (hereinafter abbreviated as IC) socket for a semiconductor IC device. Particularly, the present invention relates to an IC socket that is used to test a ball grid array (hereinafter abbreviated as BGA).

### BACKGROUND

In carrying out what is called a burn-in test to evaluate an electric characteristic, durability, and thermal resistance of an IC device such as a BGA device, an IC socket having contactors conductively connectable to terminals of the IC device is used. Usually, the burn-in test is carried out in a state that the IC device or the IC socket holding the IC device is disposed within an oven at 125° C., for example. In this case, an IC chip itself contained in the IC device is heated by electric conduction, and is further heated to a higher temperature than 125° C. In general, there is a high possibility that an IC chip is broken when a temperature of the IC chip exceeds 125° C. Therefore, during the test, the heat of the IC chip needs to be dissipated by a certain method.

In order to promote heat dissipation from a heated IC device, various proposals are made. For example, Japanese Patent Application Unexamined Publication No. 8-17533 discloses a socket in which a socket body is made of a material having high thermal conductance. The material is a ceramic, for example, and generated heat of the integrated circuit is dissipated via the socket body.

FIGS. 9(a) and (b) are a side view and a top plan view (a bottom view), respectively, of a BGA device 100 having thermal balls. The BGA device 100 has a square shape having about 20 mm to 40 mm in one side as viewed from the top, and includes an IC chip 102 sealed with resin, solder signal balls 104 that are electrically connected to the IC chip 102, and solder thermal balls 106 that are disposed in a region close to the IC chip 102 (usually at the center of the device).

FIG. 10 is a schematic side cross-sectional view of an IC socket 200 that is used to test the BGA device 100. The IC socket 200 is disposed on a printed circuit board 202, and has a main body 204 made of resin, and plural contact pins 206a and 206b. Each contact pin 206a is fixed to the main body 204 so as to be brought into contact with each signal ball 104 of the BGA device 100. On the other hand, each contact pin 206b is fixed to the main body 204 so as to be brought into contact with each thermal ball 106 of the BGA device 100. Because each contact pin is made of a material having high electric conductance and thermal conductance such as copper alloy, the contact pins 206a that are brought into contact with the signal balls 104 can transmit signals from the signal balls to the printed circuit board. On the other hand, the contact pins 206b that are brought into contact with the thermal balls 106 operate as heat-dissipation paths (indicated by arrowheads) that transmit heat of the heated BGA device (IC chips) to the printed circuit board.

According to the conventional configurations as shown in FIG. 9 and FIG. 10, the region in which the heat-dissipation contactors are disposed, that is, the region where thermal balls 106 are disposed, is limited to the substantially narrow region (the region shown by a broken line in FIG. 9(b)) on the lower surface of the IC device close to the resin-sealed IC chip 102. Therefore, in the case of a high-output BGA device, that is, when a heat value of the IC chip 102 is large, a heat conduction amount via the thermal balls 106 and the contact pins 206b is insufficient to prevent undesirable overheating of the BGA device. However, even when heat is to be dissipated (heat is to be transmitted) from the region of the lower surface of the BGA device at a relatively far distance from the IC chip 102, a heat conduction amount from the IC chips to parts other than the thermal balls is small, because the device main body is made of resin having relatively low thermal conductance. As a result, the heat dissipation effect is small.

In Japanese Patent Application Unexamined Publication No. 8-17533, it is proposed that the socket main body is structured by an insulating ceramic, in order to insulate (not electrically short-circuit) each terminal. However a ceramic is generally expensive, and has a problem of difficulty in precision forming. Although a ceramic is a material of high thermal conductance as an insulating material, this thermal conductance is lower than thermal conductance of a metal material such as copper alloy.

### SUMMARY

It is an object of at least one embodiment of the present invention to provide an IC socket that has a configuration to promote heat dissipation from an IC device in a simple configuration, and prevent overheating of the IC device under test.

In order to achieve the above object, one embodiment of the invention described provides an IC socket including a socket main body in which an IC device can be disposed, and plural first contactors and plural second contactors that are disposed in a lower projection region of the IC device disposed on the socket main body. The first contactors are electrically connected to the IC device, and the second contactors are not electrically connected to the IC device and are thermally connected to the IC device. The IC socket includes a heat spreader that is made of a material having higher thermal conductivity than thermal conductivity of the socket main body, and that thermally connects each of the second conductors.

In a further embodiment of the invention the heat spreader is made of a plate material formed with reception holes to the internal surface of which the second contactors are contacted.

In yet a further embodiment of the invention each second contactor has a part having one side surface of approximately a square pole removed, and each reception hole of the heat spreader has approximately a quadrangle to the internal surface of which the square pole can be contacted.

A further embodiment of the invention includes third contactors that are disposed in regions not owned by the first and the second contactors in the lower projection region, and that are not electrically connected to the IC device, wherein the heat spreader is thermally connected to the second contactors and the third contactors.

In yet a further embodiment of the invention the heat spreader is made of a plate material formed with reception holes to the inner surface of which the second and the third contactors are contacted.

In yet a further embodiment of the invention the second and the third contactors have a part having one side surface of approximately a square pole removed, and the reception holes of the heat spreader has approximately a quadrangle to the internal surface of which the square pole can be contacted.

In yet a further embodiment of the invention the first contactors, the second contactors, and the third contactors are the same.

In yet a further embodiment of the invention the heat spreader is made of a metal material selected from a group including copper alloy and aluminum.

In yet a further embodiment of the invention the IC device is a BGA device, the first contactors are brought into contact with signal balls of the BGA device, and the second contactors are brought into contact with thermal balls of the BGA device.

According to the IC socket of the present invention, thermal resistance of the IC socket can be decreased to a level lower than conventional thermal resistance. Therefore, even when a heat value of the IC device is large, a rise in the temperature of the IC device can be suppressed, and a trouble due to the heat of the IC device can be avoided. Further, by using the third contactors, a new heat dissipation path is provided, thereby further decreasing thermal resistance.

Because the second and the third contactors are not electrically connected to the IC device, there is no problem when the heat spreader is connected not only thermally but also electrically to the second and the third contactors. Therefore, the heat spreader can be formed by a metal material having extremely high thermal conductance.

The connection between the heat spreader and the second and the third contactors can be achieved in a simple configuration that the contactors are inserted into reception holes formed on the heat spreader as a plate member.

When the reception holes are formed in approximately a square hole and also when a part of each contactor contacted to each reception hole is formed as a square pole having one side removed, a sufficient contact area between the heat spreader and the contactor can be secured while maintaining a manufacturing of each contactor by punching out the contactor from the plate member and bending the contactor.

The first contactors, the second contactors, and the third contactors can be manufactured using the same material and in the same shapes. Therefore, this is advantageous from the viewpoint of manufacturing cost and part management.

The IC socket according to the present invention is particularly suitable to test a BGA device that includes signal balls and thermal balls.

### BRIEF DESCRIPTION OF THE DRAWINGS

FIG. 1 is an outline perspective view of an IC socket according to a preferred embodiment of the present invention.

FIG. 2 is a side cross-sectional view of the IC socket shown in FIG. 1.

FIG. 3 is a perspective view of a contact pin.

FIG. 4 shows a state of a contact between a crotch of a contact pin and signal balls of a BGA device.

FIG. 5 shows a heat spreader according to one embodiment.

FIG. 6 shows a state that a heat spreader is disposed on the upper surface of a socket main body of the IC socket according to the present invention.

FIG. 7 shows a state that contact pins are pierced through a heat spreader.

FIG. 8 is a horizontal cross-sectional view showing a state of a contact between a heat spreader and contact pins.

FIG. 9(a) is a side view of a BGA device, and FIG. 9(b) is a top plan view of the BGA device.

FIG. 10 is a side cross-sectional view of a conventional IC socket.

### DETAILED DESCRIPTION

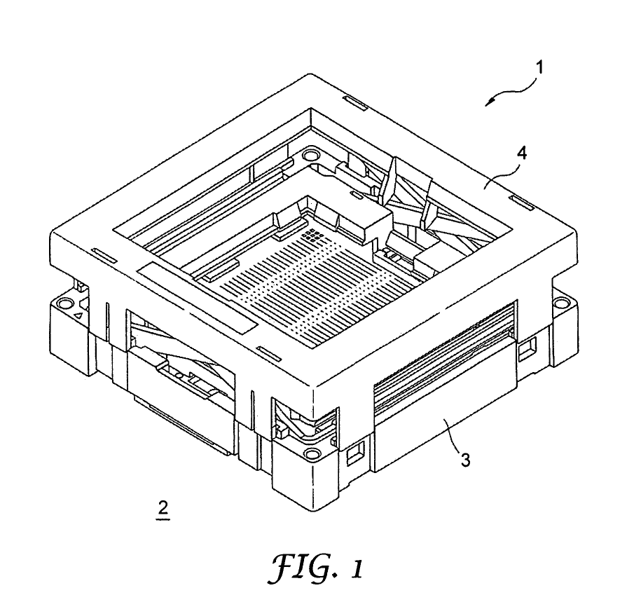

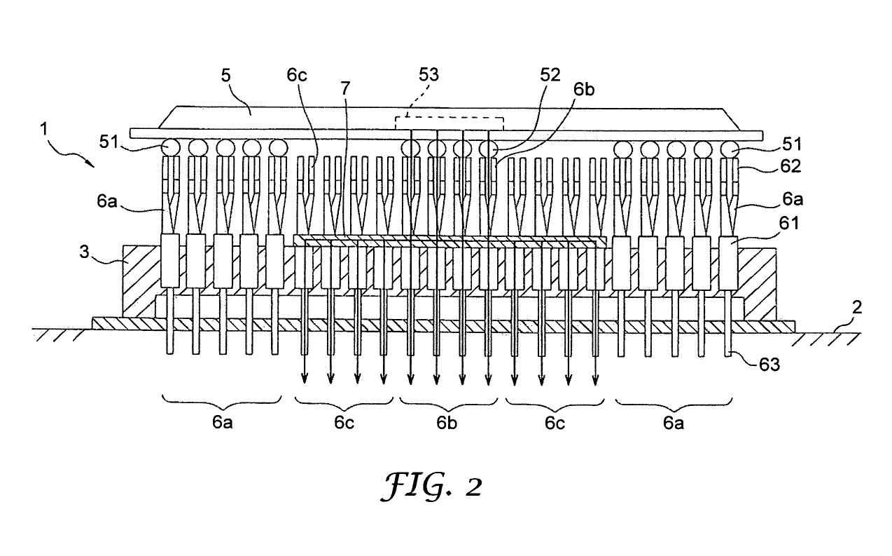

FIG. 1 is an external perspective view of an IC socket 1 according to the present invention, and FIG. 2 is a schematic side cross-sectional view of the IC socket 1 shown in FIG. 1. The IC socket 1 is disposed on a printed circuit board 2, and has a socket main body 3 made of an insulating material such as resin, and a frame 4 that can be moved in up and down directions relative to the socket main body 3 and that is biased upward. The IC socket 1 has constituent elements such as a nest, a guide, and a lever, in addition to the frame 4. Because these additional constituent elements are known, their explanations are omitted, and are not shown in FIG. 2 either, for simplification. As shown in FIG. 2, the socket main body 3 has plural contactors, that is, first contact pins 6a and second contact pins 6b, that are used to electrically or thermally connect a BGA device 5, to be tested and disposed on an upper part, to the printed circuit board 2, in a lower projection region of the BGA device 5. Like in the above conventional configuration, the first contact pins 6a are conductively connected to an IC chip 53 that is sealed with resin at approximately the center of the BGA device 5, and are fixed to the socket main body 3 so as to be brought into contact with signal balls 51 disposed in an external periphery region of the lower surface of the BGA device. On the other hand, the second contact pins 6b are fixed to the socket main body 3 so as to be brought into contact with thermal balls 52 disposed on the lower surface of the BGA device 5 close to the IC chip 53, to dissipate heat from the BGA device 5.

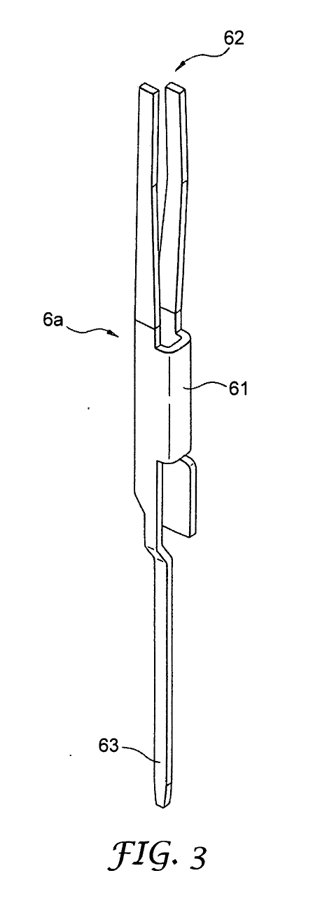

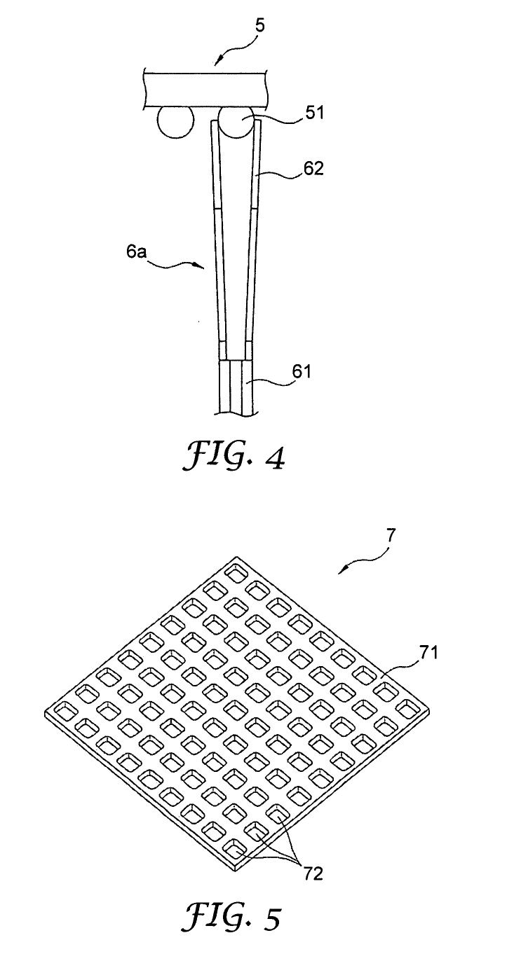

FIG. 3 is a perspective view showing a configuration of the first contact pint 6a. From a viewpoint of manufacturing cost, it is advantageous to form the first contact pin 6a by punching out a metal plate having high electric conductance and thermal conductance, such as copper alloy, and bending this punched metal plate. As shown in FIG. 3, the first contact pin 6a has a core part 61, a crotch 62 that is extended upward from the core part 61 and is brought into contact with a signal ball 51 to hold this signal ball 51 at a test time, and a leg part 63 that is extended downward from the core part 61 and is connected to the printed circuit board 2 at the test time. The IC socket is structured such that the crotch 62 is expanded when the frame 4 (see FIG. 1) is pressed downward. To connect the BGA device 5 to the IC socket 1, the frame 4 is first pressed downward to mount the BGA device 5 on the socket main body 3 of the IC socket 1, in a state that the crotch 62 is opened. Next, the frame 4 is returned to the original position, and the crotch 62 is closed. With this arrangement, the crotch 62 of each contact pin holds the signal ball 51 or the thermal ball 52 provided on the lower surface of the BGA device 5. The function of this frame 4 is known.

It is preferable that the contact pins 6a and 6b, and contact pins 6c described later are made of the same material and are formed in the same shapes, as shown in FIG. 3. This is because the same material and the same shape are advantageous from the viewpoint of parts management as well as manufacturing cost. Further, as far as when the number of the signal balls 51 does not exceed the number of the first contact pins 6a, the same IC socket can be used, even when the number of the thermal balls 52 increases.

The present invention has the following characteristics. As shown in FIG. 2, preferably, contactors similar to the contact pins 6a and 6b, that is, the third contact pins 6c, are disposed so as not to be electrically contacted to the BGA device 5, in regions not corresponding to the signal balls 51 and the thermal balls 52 of the BGA device 5, that is, in “space regions” not owned by the contact pins 6a and 6b in the lower projection region of the BGA device 5. Further, the third contact pins 6c and the second contact pins 6b that are contacted to the thermal balls 52 are connected to each other via a material having higher thermal conductivity than thermal conductivity of the socket main body 3.

Specifically, as shown in FIG. 2, a heat spreader 7 that is contacted to all the second and the third contact pins 6b and 6c are disposed on the socket main body. The heat spreader 7 is made of a material having higher thermal conductivity than thermal conductivity of the socket main body 3. The heat spreader 7 is formed to have plural receptors, that is, reception holes 72, arrayed to allow the contact pins 6b and 6c to pass through the reception holes 72, on a plate member 71, as shown in FIG. 5.

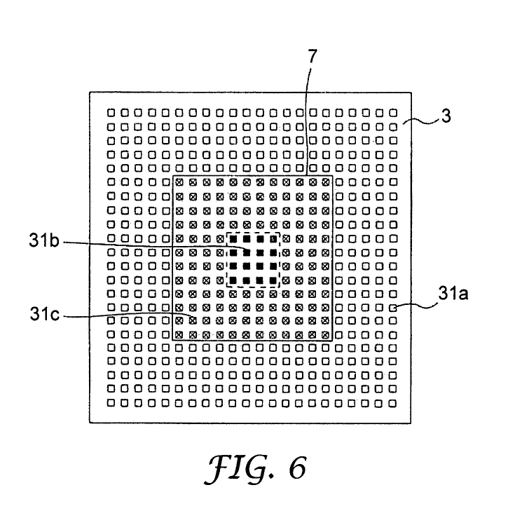

FIG. 6 is a top plan view of the socket main body 3 on which the heat spreader 7 is disposed. The socket main body 3 has through-holes 31a, 31b, and 31c through which the contact pints 6a and 6b are pierced. The layout of the reception holes 72 of the heat spreader 7 matches the layout of the through-holes 31b and 31c. The heat spreader 7 is disposed on the socket main body 3 such that each reception hole 72 is continuous to each through-hole 31 of the socket main body 3.

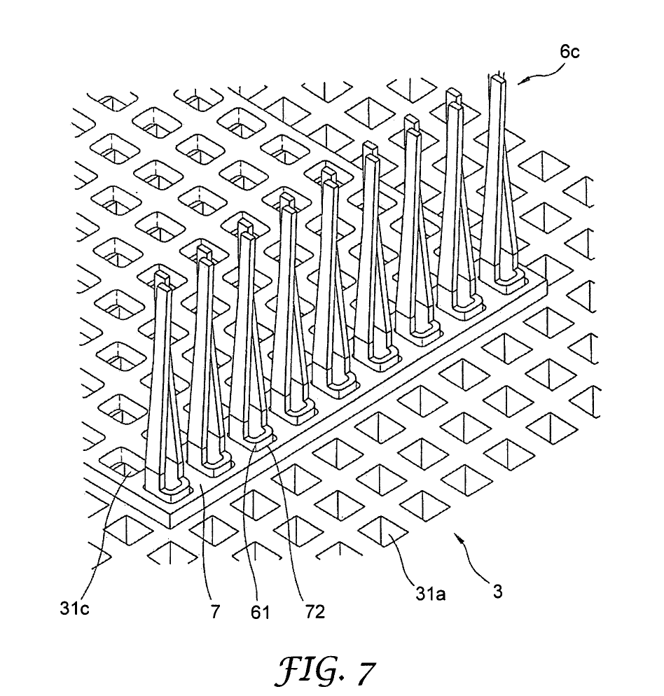

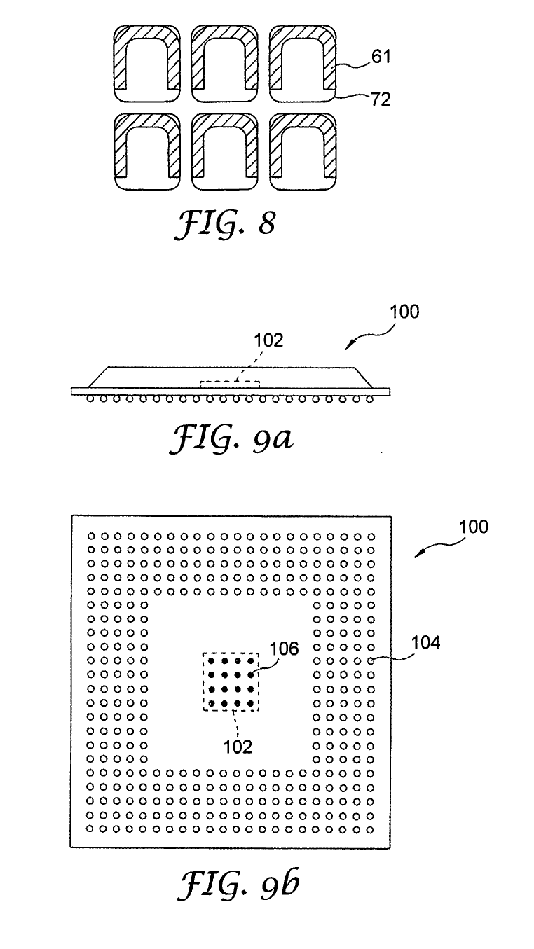

FIG. 7 shows a state of a contact between the reception holes 72 of the heat spreader 7 and the contact pins. In FIG. 7, only a part of the third contact pins 6c are shown as contact pins, for the sake of clarification. Each contact pin (the contact pin 6c in the example shown in the drawing) is disposed so that the core part 61 is brought into contact with the inner part of the reception hole 72 of the heat spreader 7. As shown in FIG. 3, the core part 61 of the contact pin 6c has such a shape that one side surface of approximately a square pole is removed. On the other hand, each reception hole 72 of the heat spreader 7 has approximately a quadrangle to the internal surface of which the square pole can be contacted, as shown in FIG. 8. Therefore, the remaining three sides of the square pole, that is, a greater part of the external surface of the core part 61, can be contacted to the reception hole. Based on this configuration, heat can be sufficiently transmitted from the contact pins 6b and 6c to the heat spreader 7.

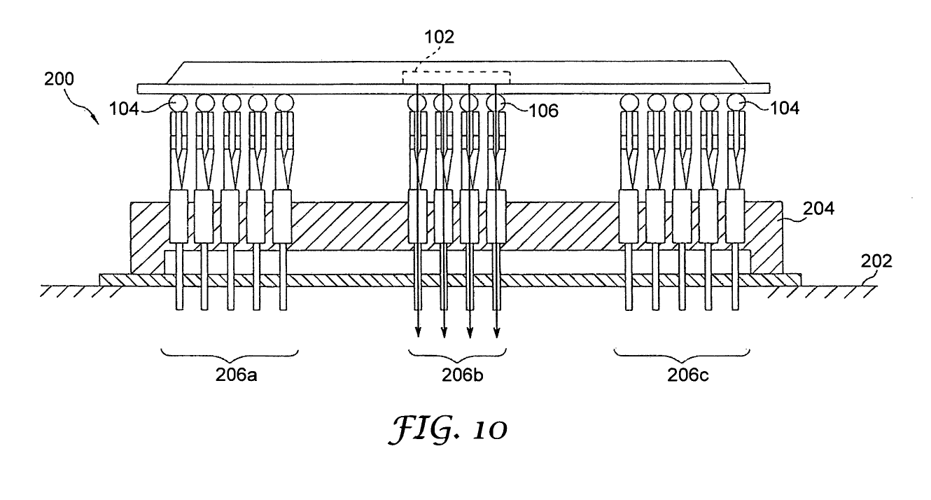

In FIG. 2, heat dissipation paths that are used when the IC socket according to the present invention are used are shown in arrowheads. According to the conventional IC socket shown in FIG. 10, heat dissipation paths are limited to paths from the thermal balls to the printed circuit board via the contact pins that are contacted to the thermal balls. However, according to the present invention, the heat spreader 7 is thermally contacted to the second and the third contact pins 6b and 6c. Therefore, in addition to the above heat dissipation paths, additional heat dissipation paths are formed, from the second contact pins 6b that are contacted to the thermal balls to the printed circuit board 2, via the heat spreader 7 and the third contact pins 6c. Consequently, thermal resistance of the total IC socket from the BGA device 5 to the printed circuit board 2 can be decreased to a level lower than the conventional thermal resistance, and a rise in the temperature of the BGA device under the test can be suppressed. Heat value transmitted to the printed circuit board 2 can be properly dissipated to the outside by a heat sink not shown.

Because the heat spreader 7 is used to decrease the thermal resistance of the IC socket 1, this material has higher thermal conductivity than the thermal conductivity of the socket main body 3. The second and the third contact pins 6b and 6c that are thermally connected to the heat spreader 7 are not electrically connected to the BGA device. Therefore, there is no inconvenience when the contact pins 6b and 6c are also electrically connected. Accordingly, it is preferable that the material of the heat spreader 7 is selected from a group including metal materials having very high thermal conductance such as copper alloy like beryllium copper, and aluminum. However, it is also possible to thermally connect the heat spreader to all contact pins including the contact pins 6a. In other words, the contact pins 6a can be used not only as signal transmission paths but also as heat dissipation paths. However, in this case, because each contact pin 6a cannot be electrically connected to other contact pin, the heat spreader is made of a material having relatively high thermal conductance as an insulation material.

In order to confirm the validity of the IC socket according to the present invention, a test is carried out to compare the IC socket using the third contact pins according to the present invention with the conventional IC socket. In the test, a dummy device, simulating a heat generation of an IC chip, is mounted on each IC socket, a rise in the temperature of the device at a constant output is measured, and thermal resistance of each IC socket is calculated. As a result, it becomes clear that the thermal resistance of the IC socket according to the present invention is lower than the thermal resistance of the IC socket by about 10° C. In other words, when BGA devices of the output of two W are used, a difference of about 20° C. occurs between the temperature of the device according to the present invention and the temperature of the conventional device, under the test. As described above, according to a general-purpose BGA device, a risk of the occurrence of a trouble increases rapidly when the temperature of the device exceeds 150° C. Therefore, the present invention has a large advantage in that the temperature of the device can be decreased by about 20° C. from the conventional temperature, in the same condition. When a device of higher output is used, this advantage increases more.

In the embodiment shown in the drawings, the third contact pins are additionally provided and are thermally connected to the second pins. However, instead of using the third contact pins, a similar heat spreader can be used to thermally connect each second contact pin to the heat spreader. In the IC device, only the IC chip is heated. Because the thermal conductivity of the material of the IC package is low, the thermal balls immediately below the IC chip have a higher temperature than the temperature of the thermal balls disposed around the IC chip. Therefore, temperature groups occur between the contact pins. When each second contact pin is thermally connected, the temperature groups of the IC socket main body due to the heating of the BGA device can be made uniform to a certain level. Consequently, heat dissipation to the printed circuit board can be promoted.

1. An IC socket comprising a socket main body in which an IC device is disposed, and plural first contactors and plural second contactors that are disposed in a lower projection region of the IC device disposed on the socket main body, the first contactors being electrically connected to the IC device, the second contactors being not electrically connected to the IC device and thermally connected to the IC device,
wherein the IC socket includes a heat spreader that is made of a material having higher thermal conductivity than thermal conductivity of the socket main body, and that thermally connects each of the second conductors.

2. The IC socket as set forth in claim 1, wherein the heat spreader is made of a plate material formed with reception holes to the internal surface of which the second contactors are contacted.

3. The IC socket as set forth in claim 2, wherein each second contactor has a part having one side surface of approximately a square pole removed, and each reception hole of the heat spreader has approximately a quadrangle to the internal surface of which the square pole is contacted.

4. The IC socket as set forth in claim 1, further including third contactors that are disposed in regions not owned by the first and the second contactors in the lower projection region, and that are not electrically connected to the IC device, wherein the heat spreader is thermally connected to the second contactors and the third contactors.

5. The IC socket as set forth in claim 4, wherein the heat spreader is made of a plate material formed with reception holes to the inner surface of which the second and the third contactors are contacted.

6. The IC socket as set forth in claim 5, wherein the second and the third contactors have a part having one side surface of approximately a square pole removed, and the reception holes of the heat spreader has approximately a quadrangle to the internal surface of which the square pole is contacted.

7. The IC socket as set forth in claim 4, wherein the first contactors, the second contactors, and the third contactors are the same.

8. The IC socket as set forth in claim 1, wherein the heat spreader is made of a metal material selected from a group including copper alloy and aluminum.

9. The IC socket as set forth in claim 1, wherein the IC device is a BGA device, the first contactors are brought into contact with signal balls of the BGA device, and the second contactors are brought into contact with thermal balls of the BGA device.
